(19) United States
(12) Patent Application Publication
(10) Pub. No.: US 2016/0260724 A1
(43) Pub. Date: Sep. 8, 2016

(54) SEMICONDUCTOR DEVICE AND MANUFACTURING METHOD OF SEMICONDUCTOR DEVICE

(71) Applicant: Kabushiki Kaisha Toshiba, Minato-ku (JP)

(72) Inventor: Takashi OHASHI, Yokkaichi (JP)

(73) Assignee: Kabushiki Kaisha Toshiba, Minato-ku (JP)

(21) Appl. No.: 14/733,007

(22) Filed: Jun. 8, 2015

Related U.S. Application Data
(60) Provisional application No. 62/129,356, filed on Mar. 6, 2015.

(51) Int. Cl. H01L 27/115

(52) U.S. Cl. CPC H01L 27/11521

(57) ABSTRACT

According to one embodiment, a semiconductor device includes a pair of selection gate transistors arranged on a semiconductor layer, and memory cell transistors arranged on the semiconductor layer between the pair of selection gate transistors. The memory cell transistors are connected to each other in series such that every two adjacent ones of the memory cell transistors share a source/drain region. Further, the memory cell transistors are arranged in an odd number between the pair of selection gate transistors.

### CROSS-REFERENCE TO RELATED APPLICATIONS

This application is based upon and claims the benefit of priority from U.S. Provisional Application No. 62/129,356, filed on Mar. 6, 2015; the entire contents of which are incorporated herein by reference.

### FIELD

Embodiments described herein relate generally to a semiconductor device and a manufacturing method of a semiconductor device.

### BACKGROUND

Conventionally, when a nonvolatile semiconductor memory device, such as a NAND type flash memory, is manufactured, core material patterns different in size are formed in the memory cell part and in the peripheral circuit part together by one process using a lithography technique. Thereafter, sidewall patterns are formed around the core material patterns by use of a sidewall processing process, and the core material patterns are removed. Then, the remaining sidewall patterns are used to process a processing object on the lower side.

### BRIEF DESCRIPTION OF THE DRAWINGS

FIG. 1 is an equivalent circuit diagram showing part of a memory cell array formed in a memory cell region of a NAND type flash memory device;

FIG. 2 is a plan view showing some of the layout patterns of the memory cell region;

FIG. 3 is a sectional view taken along a line A-A in FIG. 2;

FIGS. 4A to 4H are partial sectional views schematically showing an example of a pattern formation method according to a first embodiment;

FIG. 5 is a sectional view schematically showing an example of a configuration of a nonvolatile semiconductor memory device according to the first embodiment;

FIGS. 6A to 6C are sectional views schematically showing a pattern formation method according to a comparative example;

FIGS. 7A to 7E are partial sectional views schematically showing an example of a pattern formation method according to a second embodiment; and

FIGS. 8A to 8E are partial sectional views schematically showing an example of a pattern formation method according to a third embodiment.

### DETAILED DESCRIPTION

In general, according to one embodiment, a semiconductor device includes a pair of selection gate transistors arranged on a semiconductor layer, and memory cell transistors arranged on the semiconductor layer between the pair of selection gate transistors. The memory cell transistors are connected to each other in series such that every two adjacent ones of the memory cell transistors share a source/drain region. Further, the memory cell transistors are arranged in an odd number between the pair of selection gate transistors.

Exemplary embodiments of a semiconductor device and a manufacturing method of a semiconductor device will be explained below in detail with reference to the accompanying drawings. The present invention is not limited to the following embodiments. The sectional views and the plan view of a semiconductor device used in the following embodiments are schematic, and so the relationship between the thickness and width of each layer and/or the thickness ratios between respective layers may be different from actual states.

### First Embodiment

The embodiment described hereinafter is applied to a manufacturing method of a NAND type flash memory device as an example of a semiconductor device. The NAND type flash memory device includes a memory cell region and a peripheral circuit region. The memory cell region is a region where a number of memory cell transistors (which will also be referred as memory cells, hereinafter) are arranged in a matrix shape. The peripheral circuit region is a region that includes peripheral circuit transistors for driving the memory cells.

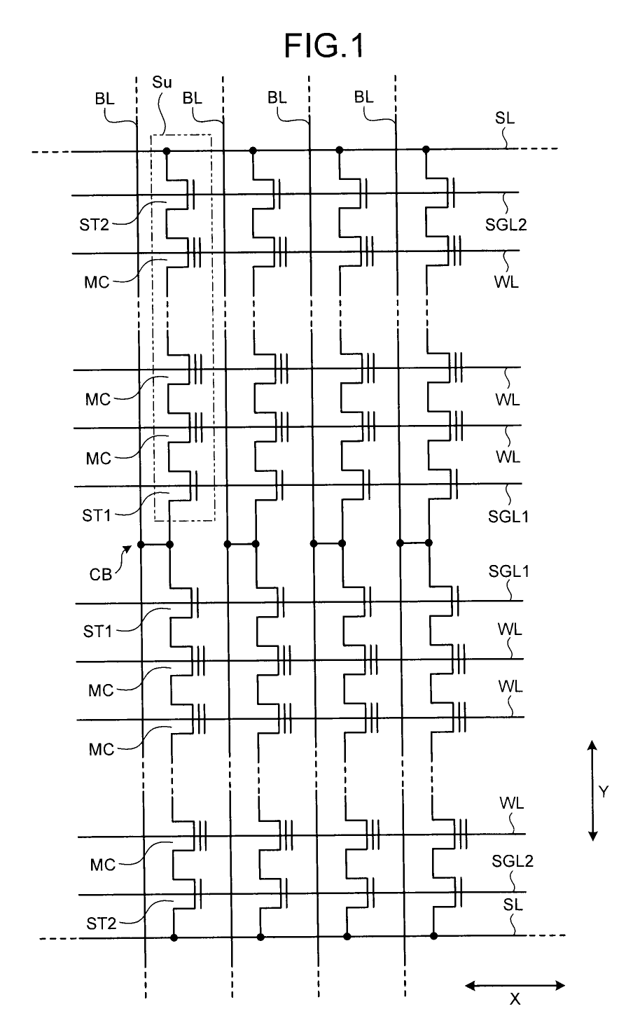

FIG. 1 is an equivalent circuit diagram showing part of a memory cell array formed in a memory cell region of a NAND type flash memory device. The memory cell array of the NAND type flash memory device has a structure in which NAND cell units (memory units) Su are arranged in rows and columns. Each NAND cell unit Su is composed of two selection gate transistors ST1 and ST2 and a string of memory cells. The string of memory cells has a structure in which a plurality of memory cells MC are connected in series between the two selection gate transistors ST1 and ST2. In each NAND cell unit Su, the plurality of memory cells MC are formed such that every two adjacent ones of them share a source/drain region.

Memory cells MC arrayed in an X-direction in FIG. 1 (which corresponds to a word line direction and a gate width direction) are connected in common by a word line (control gate line) WL. Further, selection gate transistors ST1 arrayed in the X-direction in FIG. 1 are connected in common by a selection gate line SGL1, and selection gate transistors ST2 arrayed in the X-direction are connected in common by a selection gate line SGL2. Each selection gate transistor ST1 is connected through its drain region to a bit line contact CB. One end of this bit line contact CB is connected to a bit line BL extending in a Y-direction in FIG. 1 (which corresponds to a bit line direction and a gate length direction) perpendicular to the X-direction. Further, each selection gate transistor ST2 is connected through its source region to a source line SL extending in the X-direction in FIG. 1.

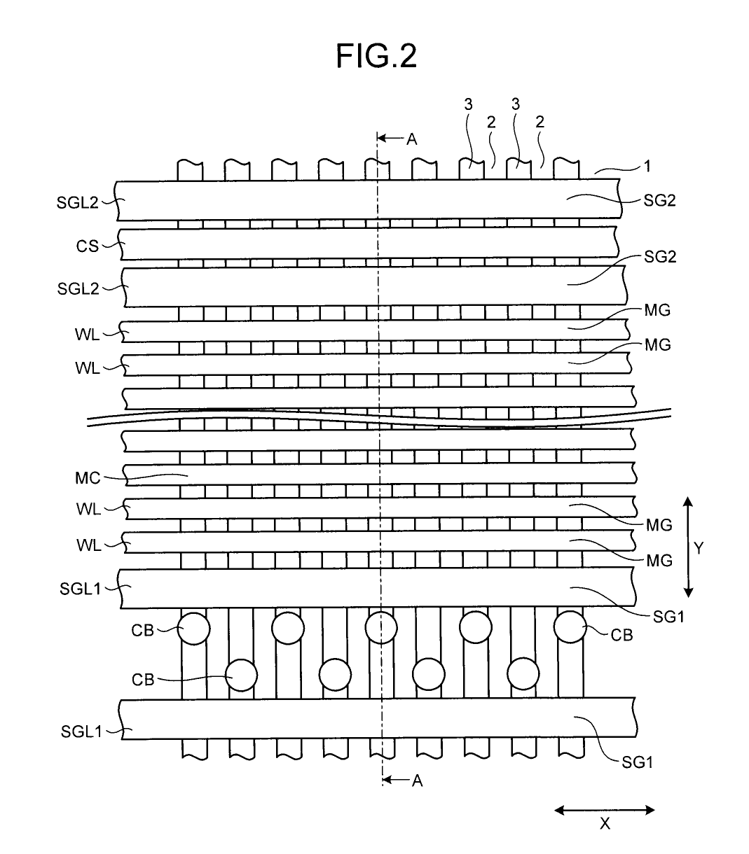

FIG. 2 is a plan view showing some of the layout patterns of the memory cell region. In a semiconductor substrate 1, a plurality of STIs (Shallow Trench Isolation) 2 serving as element isolation regions are formed to extend in the Y-direction in FIG. 2 and to be present at predetermined intervals in the X-direction. The STIs 2 form a state where active regions 3 are isolated from each other between every two adjacent ones of them in the X-direction in FIG. 2. Word lines WL for the memory cells MC are formed to extend in the X-direction in FIG. 2 perpendicular to the active regions 3 and to be present at predetermined intervals in the Y-direction, as in a line-and-space form.

Further, two selection gate lines SGL1 are formed to extend in the X-direction in FIG. 2 and to be adjacent in parallel with each other. Bit line contacts CB are formed to the portions of the active regions 3 between the two selection gate lines SGL1 adjacent to each other. In this example, the bit line contacts CB are arranged at positions alternately varied in the Y-direction between every two adjacent ones of the active regions 3. More specifically, between the two selection gate lines SGL1, some of the bit line contacts CB are arranged closer to one of the selection gate lines SGL1, and the others of the bit line contacts CB are arranged closer to the other of the selection gate lines SGL1. In other words, the bit line contacts CB are arranged in a zigzag state.

Similarly to the selection gate lines SGL1, two selection gate lines SGL2 are formed to extend in the X-direction in FIG. 2 and to be in parallel with each other, at positions separated from the selection gate lines SGL1 with a predetermined number of word lines WL interposed therebetween. Here, a source line contact CS is arranged at the portions of the active regions 3 between the two selection gate lines SGL2.

On the portions of the active regions 3 intersecting with the word line WL, the stacked gate structures MG of the memory cells MC are respectively formed. Further, on the portions of the active regions 3 intersecting with the selection gate lines SGL1 and SGL2, the gate structures SG1 and SG2 of the selection gate transistors ST1 and ST2 are formed.

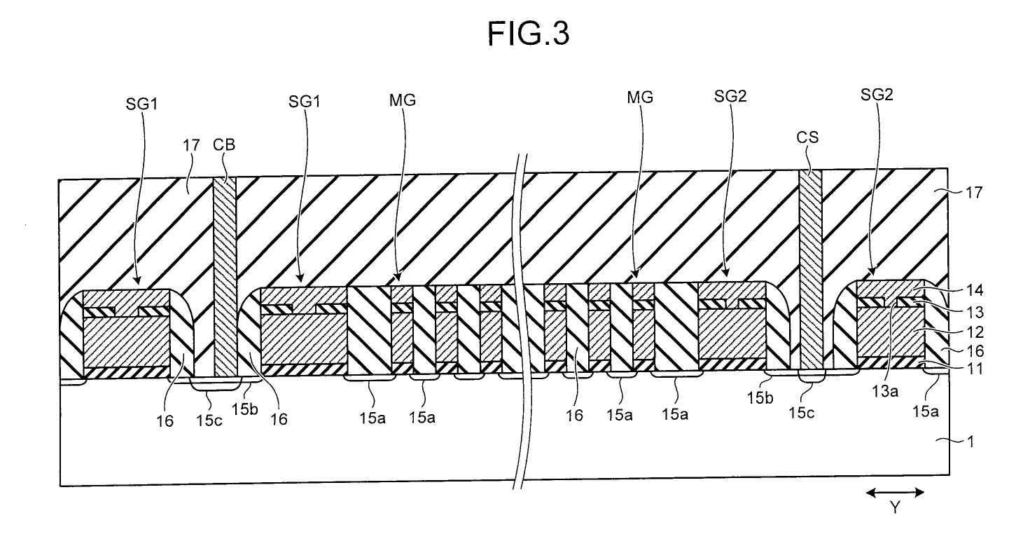

FIG. 3 is a sectional view taken along a line A-A in FIG. 2. Specifically, this shows the gate structures SG1 and SG2 of selection gate transistors ST1 and ST2 and the stacked gate structures MG of memory cells MC arranged between these two selection gate transistors ST1 and ST2, at an active region 3. As shown in FIG. 3, each of the stacked gate structures MG of the memory cells MC and the gate structures SG1 and SG2 of the selection gate transistors ST1 and ST2 has a structure in which a floating gate electrode film 12, an inter-electrode insulating film 13, and a control gate electrode film 14 are stacked in this order on the semiconductor substrate 1 through a tunnel insulating film 11. Here, an opening 13a is formed in the inter-electrode insulating film 13 of each of the gate structures SG1 and SG2 of the selection gate transistors ST1 and ST2. A control gate electrode film 14 is embedded in this opening 13a. Consequently, the floating gate electrode film 12 and the control gate electrode film 14 are electrically connected to each other. In this way, in each of the selection gate transistors ST1 and ST2, a gate electrode is constituted by the floating gate electrode film 12 and the control gate electrode film 14.

The semiconductor substrate 1 may be formed of a silicon substrate or the like. The tunnel insulating film 11 may be formed of a thermal oxide film, thermal oxynitride film, CVD (Chemical Vapor Deposition) oxide film, CVD oxynitride film, insulating film with Si sandwiched therein, or insulating film with Si embedded therein in dot patterns. The floating gate electrode film 12 may be made of polycrystalline silicon doped with an N-type impurity or P-type impurity, may be formed of a metal film, or poly-metal film, which employs Mo, Ti, W, Al, or Ta, or may be formed of a nitride film. The inter-electrode insulating film 13 may be formed of a silicon oxide film, silicon nitride film, or ONO (Oxide-Nitride-Oxide) film having a stacked structure of silicon oxide films and a silicon nitride film, or may be formed of a high dielectric constant film, such as an aluminum oxide film or hafnium oxide film, or a stacked structure of a high dielectric constant film and a low dielectric constant film, such as a silicon oxide film or silicon nitride film. The control gate electrode film 14 may be made of polycrystalline silicon doped with an N-type impurity or P-type impurity, or may be formed of a metal film or poly-metal film, which employs Mo, Ti, W, Al, or Ta, or a stacked structure of a polycrystalline silicon film and a metal silicide film.

At each of the portions between the stacked gate structures MG-MG and between the stacked gate structures MG and the gate structures SG1 and SG2, an impurity diffusion region 15a serving as a source/drain region is formed near the surface of the semiconductor substrate 1. Further, at each of the portions between the adjacent gate structures SG1-SG1 and between the adjacent gate structures SG2-SG2, an impurity diffusion region 15b serving as a source/drain region as in the diffusion region 15a is formed near the surface of the semiconductor substrate 1.

At each of the portions between a pair of adjacent stacked gate structures MG-MG, between the stacked gate structures MG and the gate structures SG1 and SG2, between the gate structures SG1-SG1, and between the gate structures SG2-SG2, a sidewall insulating film 16 formed of, e.g., a silicon oxide film is formed on sidewall surfaces. Each of the portions between the stacked gate structures MG-MG and between the stacked gate structures MG and the gate structures SG1 and SG2 is filled with the corresponding sidewall insulating film 16 thus provided. On the other hand, each of the portions between the gate structures SG1-SG1 and between the gate structures SG2-SG2 is not entirely filled with the corresponding sidewall insulating film 16, but is provided with sidewall insulating films 16 formed on sidewall surfaces facing each other.

At each of the portions between the gate structures SG1-SG1 and between the gate structures SG2-SG2, an impurity diffusion region 15c for lowering the contact resistance of the bit line contact CB or source line contact CS is formed near the surface of the semiconductor substrate 1 between the sidewall insulating films 16 facing each other. This impurity diffusion region 15c is formed to have a smaller width dimension and a larger diffusion depth (pn-junction depth), as compared with the impurity diffusion region 15b, and is formed as an LDD (Lightly Doped Drain) structure.

Further, an interlayer insulating film 17 is formed over the stacked gate structures MG and the gate structures SG1 and SG2 provided with the sidewall insulating films 16. The bit line contact CB is formed between the adjacent gate structures SG1-SG1 located at one end of the string of memory cells MC, such that it extends from the upper surface of the interlayer insulating film 17 to the surface of the semiconductor substrate 1. As described previously, the bit line contacts CB are alternately arranged to form a zigzag state when seen in the plan view, and so the bit line contact CB shown in FIG. 3 is formed at a position shifted to the right side. Further, the source line contact CS is formed between the adjacent gate structures SG2-SG2 located at the other end of the string of memory cells MC, such that it extends from the upper surface of the interlayer insulating film 17 to the surface of the semiconductor substrate 1, and extends across below the bit lines BL. However, the memory cells MC have the structure shown in FIG. 3 as a mere example, and it may have another structure.

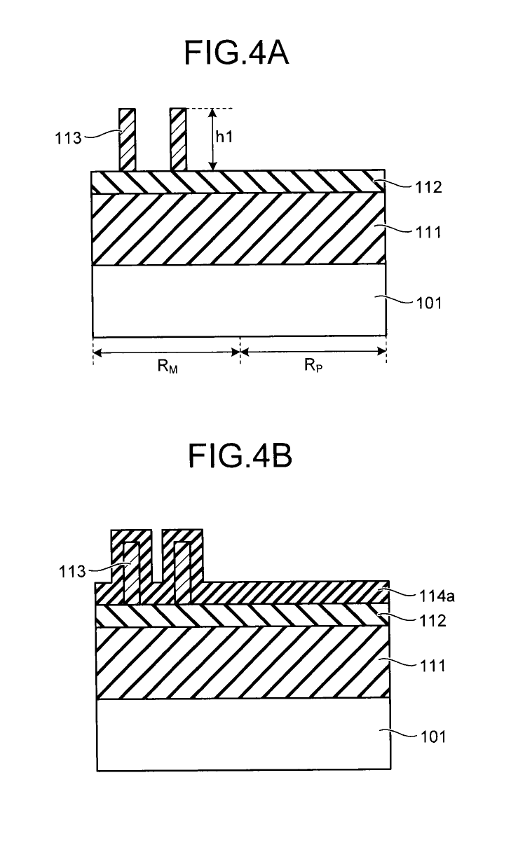

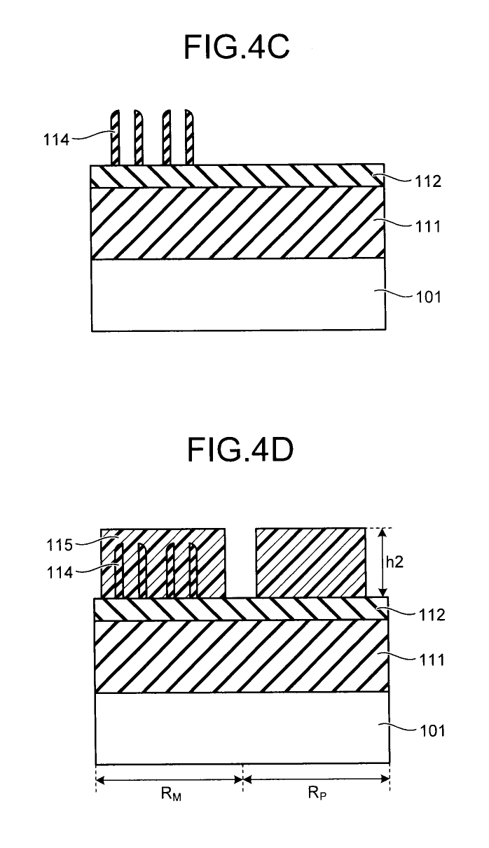

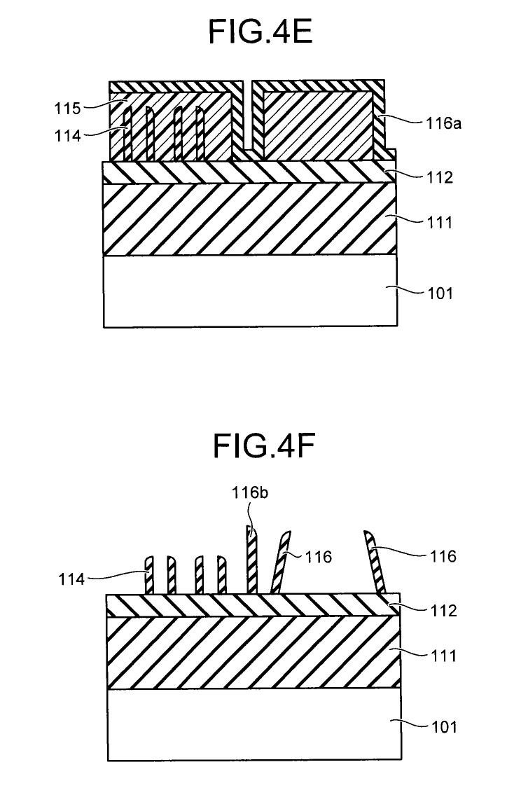

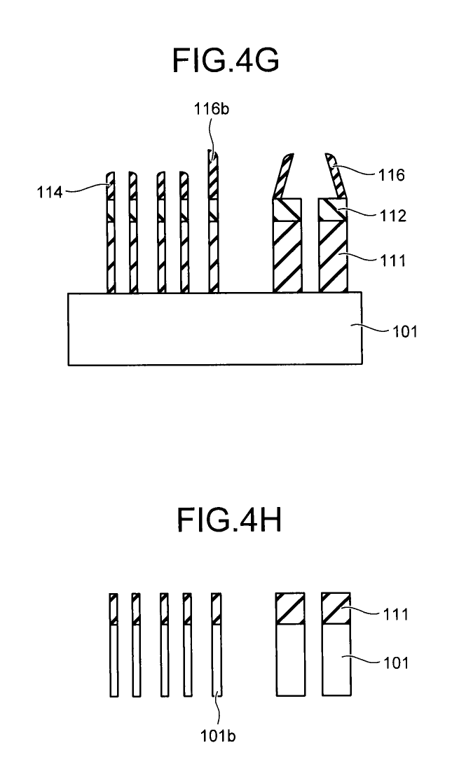

Next, an explanation will be given of a pattern formation method and a manufacturing method of a semiconductor device, by taking a formation of a NAND type flash memory device as an example. FIGS. 4A to 4H are partial sectional views schematically showing an example of a pattern formation method according to a first embodiment. Here, manufacturing steps are shown only about part of a memory cell region R_{M} and a peripheral circuit region R_{P}.

At first, as shown in FIG. 4A, a processing object film 101 is formed above a substrate, such as a silicon substrate (not shown). For example, in a case where the NAND type flash memory device shown in FIGS. 1 to 3 is manufactured, the processing object film 101 is formed of a stacked body of a tunnel insulating film, a floating gate electrode film, an inter-electrode insulating film, and a control gate electrode film.

Further, a mask film 111 and an intermediate film 112 are formed in this order on the processing object film 101. The mask film 111 and the intermediate film 112 correspond to a mask layer. The mask film 111 is made of a material that provides a selective ratio relative to the processing object film 101. The processing object film 101 may be formed of a carbon film formed by a coating method, for example. The intermediate film 112 is made of a material that provides a selective ratio relative to the mask film 111. The intermediate film 112 may be formed of an oxide film, such as a SOG (Spin on Glass) film.

Further, a resist is applied onto the entire surface of the intermediate film 112, and resist patterns 113 having a predetermined shape are formed only in the memory cell region R_{M} by use of a lithography technique. Each of the resist patterns 113 serves as a core material film. At this time, the height h1 of the resist patterns 113 is arbitrary. Here, the resist patterns 113 are patterns of a line-and-space form, in which straight line patterns are arranged at predetermined intervals in a direction perpendicular to their extending direction. The line-and-space patterns are not limited to straight line patterns. A form that may be regarded as the line-and-space patterns is of a type in which non-straight wiring lines, such as lead-out wiring lines, routing wiring lines, or U-shaped wiring lines, are arranged in a direction intersecting with their extending direction. Further, even if line patterns extending in parallel are connected to each other by connecting patterns, the portions excluding the connecting patterns may be regarded as line patterns. Here, the width of the resist patterns 113 formed as described above is defined by a pattern having the minimum size of the patterns formed above the substrate.

Then, as shown in FIG. 4B, a sidewall film 114a is formed on the intermediate film 112 including the resist patterns 113 formed thereon. The sidewall film 114a is formed to cover the side surfaces and upper surfaces of the resist patterns 113. The thickness of the sidewall film 114a may be set substantially equal to the width of the resist patterns 113, for example. The sidewall film 114a may be formed of an oxide film, such as a silicon oxide film, for example.

Thereafter, as shown in FIG. 4C, the sidewall film 114a is etched back by use of wet etching or dry etching. More specifically, part of the sidewall film 114a on the intermediate film 112 and the resist patterns 113 is removed, so that sidewall patterns 114 formed of part of the sidewall film 114a are formed around the resist patterns 113. Further, the resist patterns 113 each serving as a core material film are removed by use of a resist stripping technique employing an oxygen based gas. Consequently, there is provided a state where the sidewall patterns 114 each having a looped shape are arranged on the intermediate film 112 in the memory cell region R_{M}.

Then, as shown in FIG. 4D, a resist is applied onto the entire surface of the intermediate film 112 including the sidewall patterns 114 formed thereon, and resist patterns 115 having a predetermined shape are formed by use of a lithography technique. In the peripheral circuit region R_{P}, part of the resist patterns 115 is provided to form circuit elements for driving the memory cells MC, lead-out lines, and pads. Further, in the memory cell region R_{M}, part of the resist patterns 115 is provided to cover the sidewall patterns 114. Here, the height h2 of this resist patterns 115 is set larger than the height h1.

Thereafter, as shown in FIG. 4E, a sidewall film 116a is formed on the intermediate film 112 including the resist patterns 115 formed thereon. The sidewall film 116a is formed to cover the side surfaces and upper surfaces of the resist patterns 115. The sidewall film 116a may be formed of an oxide film, such as a silicon oxide film, for example.

Then, as shown in FIG. 4F, the sidewall film 116a is etched back by use of wet etching or dry etching. More specifically, part of the sidewall film 116a on the intermediate film 112 and the resist patterns 115 is removed, so that sidewall patterns 116 and 116b formed of part of the sidewall film 116a are formed around the resist patterns 115. The sidewall patterns 116 are formed in the peripheral circuit region R_{P}, and the sidewall pattern 116b is formed near the boundary between the memory cell region R_{M} and the peripheral circuit region R_{P}.

Further, the resist patterns 115 are removed by use of a resist stripping technique employing an oxygen based gas. Consequently, the sidewall patterns 116 each having a looped shape are formed on the intermediate film 112 in the peripheral circuit region R_{P}. Further, there is provided a state where the sidewall pattern 116b having a looped shape is arranged around the sidewall patterns 114 already present on the intermediate film 112 in the memory cell region R_{M}. When the resist patterns 115 are removed, the sidewall pattern 116b formed adjacent to the sidewall patterns 114 hardly tilts relative to the substrate surface, but the sidewall patterns 116 distant from the sidewall patterns 114 tilt relative to the substrate surface.

As described above, the resist patterns 113 and 115 are respectively formed by individual lithography steps for the memory cell region R_{M} and the peripheral circuit region R_{P}, and thus the height of the resist patterns 115 in the peripheral circuit region R_{P} can be set larger than the height of the resist patterns 113.

Thereafter, as shown in FIG. 4G, the intermediate film 112 is etched, through the sidewall patterns 114, 116, and 116b serving as a mask, by use of wet etching or dry etching. Consequently, the shape of the sidewall patterns 114, 116, and 116b is transferred onto the intermediate film 112. Further, the mask film 111 is etched, through the sidewall patterns 114, 116, and 116b and the patterned intermediate film 112, which serve as a mask, by use of wet etching or dry etching. Consequently, the shape of the sidewall patterns 114, 116, and 116b is transferred onto the mask film 111. Here, if the sidewall patterns 114, 116, and 116b disappear when the pattern transfer is performed to the intermediate film 112, the pattern transfer may be performed to the mask film 111 only by the intermediate film 112.

Thereafter, the intermediate film 112 and the sidewall patterns 114, 116, and 116b on the mask film 111 are removed. Here, the sidewall patterns 114, 116, and 116b and the intermediate film 112 may be set to disappear when the pattern transfer is performed to the mask film 111, by adjusting their thicknesses.

In this etching, if the etching is performed by use of an RIE (Reactive Ion Etching) method employing a fluorocarbon based gas, it is possible to chose either one of a set of conditions by which deposits due to the etching are not deposited on the side surfaces of the mask film 111, and a set of conditions by which deposits due to the etching are deposited on the side surfaces of the mask film 111. In this embodiment, the etching is performed under conditions by which deposits due to the etching are not deposited on the side surfaces of the mask film 111.

In this case, the intermediate film 112 and the mask film 111 can be cut almost perpendicular to the substrate surface, by use of the sidewall patterns 114, 116, and 116b. In other words, the top and bottom of the hole formed by this processing come to have substantially the same width. Further, at portions where the sidewall patterns 114 and 116b are almost perpendicular to the substrate surface, the width of the patterns thus formed from the intermediate film 112 and the mask film 111 becomes almost equal to the width of the sidewall patterns 114 and 116b. On the other hand, at portions where the sidewall patterns 116 are inclined relative to the substrate surface, the width of the patterns thus formed from the intermediate film 112 and the mask film 111 becomes almost equal to the width of the projected shape of the sidewall patterns 116 onto the substrate surface.

Here, the width of the portions formed from the intermediate film 112 and the mask film 111 by use of the sidewall pattern 116b becomes larger than the width of the portions formed from the intermediate film 112 and the mask film 111 by use of the sidewall patterns 114, and becomes smaller than the width of the portions formed from the intermediate film 112 and the mask film 111 by use of the sidewall patterns 116.

Thereafter, as shown in FIG. 4H, the processing object film 101 is etched, through the mask film 111 serving as a mask, by use of wet etching or dry etching. Consequently, desired patterns of processing object films 101 and 101b are respectively formed in the memory cell region R_{M} and the peripheral circuit region R_{P}. Consequently, the pattern formation method is completed.

It should be noted that, in a case where the NAND type flash memory device shown in FIGS. 1 to 3 is manufactured, the line-and-space patterns of the processing object film 101 formed in the memory cell region R_{M} become the stacked gate structures MG of memory cells MC. In this case, as shown in FIG. 4G, the processing object film 101b processed through the sidewall pattern 116b serving as a mask also becomes the stacked gate structure MG of a memory cell MC.

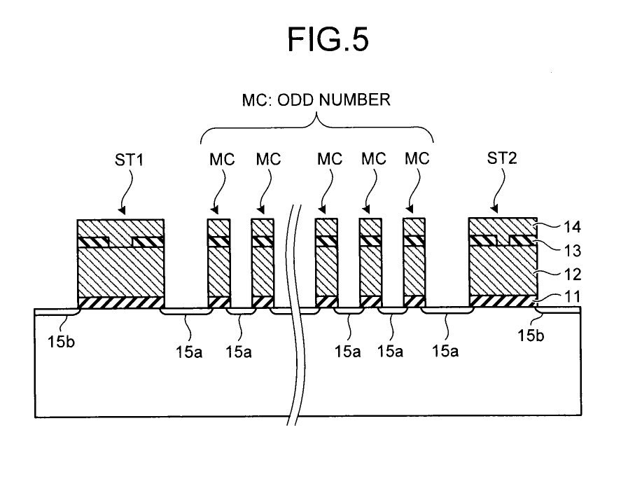

FIG. 5 is a sectional view schematically showing an example of a configuration of a nonvolatile semiconductor memory device according to the first embodiment. Here, in FIG. 5, illustration of the interlayer insulating film is omitted. Further, the constituent elements corresponding to those shown in FIG. 3 are denoted by the same reference symbols, and their description will be omitted. The opposite ends of the sidewall patterns 114 having looped shapes respectively formed around the resist patterns 113 are cut by a step not shown. Accordingly, the number of sidewall patterns 114 always becomes an even number. In addition to the processing object film 101 processed by such sidewall patterns 114, the processing object film 101b processed by the sidewall pattern 116b shown in FIG. 4G becomes the stacked gate structure MG of a memory cell MC. As a result, the number of memory cells MC arranged between a pair of selection gate transistors ST1 and ST2 becomes an odd number.

Here, in the example described above, although not shown, when the resist patterns 115 are formed in the peripheral circuit region R_{P}, as shown in FIG. 4D, patterns for forming the gate structures SG1 and SG2 of the selection gate transistors ST1 and ST2 are formed. By use of these patterns, the selection gate transistors ST1 and ST2 are formed.

Further, the stacked gate structure MG of a memory cell transistor MC arranged adjacent to one of the selection gate transistors ST1 and ST2 is a structure formed by the sidewall pattern 116b serving as a mask, as described above. Consequently, the gate length of the memory cell transistor MC arranged adjacent to one of the selection gate transistors ST1 and ST2 is larger than the gate length of the memory cell transistors MC formed by the sidewall patterns 114 serving as a mask.

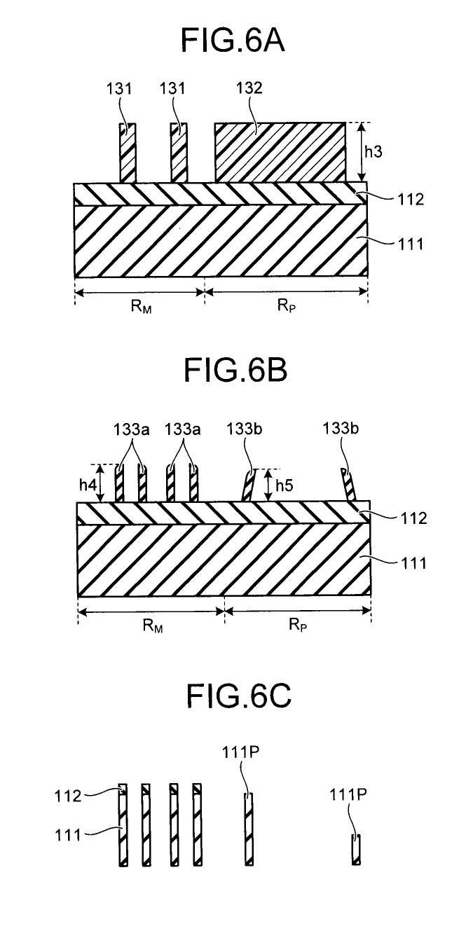

Next, an explanation will be given of effects of the first embodiment, as compared with a comparative example. FIGS. 6A to 6C are sectional views schematically showing a pattern formation method according to a comparative example. In the comparative example, at first, as shown in FIG. 6A, a resist is applied onto an intermediate film 112, and resist patterns 131 and 132 are formed in a memory cell region R_{M} and a peripheral circuit region R_{P} by use of a lithography technique. The resist patterns 131 are line-and-space patterns formed in the memory cell region R_{M}. The resist pattern 132 is a pattern having a predetermined shape formed in the peripheral circuit region R_{P}. These resist patterns 131 and 132 are formed by one lithography step. Accordingly, the resist patterns 131 and 132 have the same height h3.

Then, similarly to the sequence described in the first embodiment, a sidewall film is formed on the intermediate film 112 including the resist patterns 131 and 132 formed thereon, and the sidewall film is etched back. Then, the resist patterns 131 and 132 are removed. Consequently, as shown in FIG. 6B, sidewall patterns 133a are formed in the memory cell region R_{M}, and sidewall patterns 133b are formed in the peripheral circuit region R_{P}. When the resist patterns 131 and 132 are removed, the isolated sidewall patterns 133b in the peripheral circuit region R_{P} tend to easily tilt relative to the substrate surface. Consequently, the height h5 of the sidewall patterns 133b becomes smaller than the height h4 of the sidewall patterns 133a.

Thereafter, as shown in FIG. 6C, the sidewall patterns 133a and 133b are transferred onto the intermediate film 112 and the mask film 111 by etching. As described above, the sidewall patterns 133b are lower than the sidewall patterns 133a. Consequently, the etching amount becomes larger in the peripheral circuit region R_{P} than in the memory cell region R_{M}, and the remaining film thickness of the mask film 111P thereby becomes smaller when etching is performed in a predetermined amount. Thus, the remaining film shortage is caused in the peripheral circuit region R_{P}.

This situation can be improved by increasing the height h3 of the resist patterns 131 and 132 in FIG. 6A. However, the resist patterns 131 in the memory cell region R_{M} can collapse more easily, as the height h3 is increased. Accordingly, there is a limit in increasing the height h3 of the resist patterns 131 and 132. Thus, in the comparative example, it is difficult to overcome together the shortage of remaining film thickness in the peripheral circuit region R_{P} and the collapse of the resist patterns 131 in the memory cell region R_{M}.

On the other hand, according to the first embodiment, at first, the resist patterns 113 are formed as first line-and-space patterns in the memory cell region R_{M} by use of a first lithography technique. Then, the sidewall patterns 114 are formed by use of the resist patterns 113. Thereafter, the resist patterns 115 are formed by use of a second lithography technique, such that part of them covers the sidewall patterns 114 in the memory cell region R_{M}, and part of them has a predetermined shape in the peripheral circuit region R_{P}. The resist patterns 115 are formed higher than the resist patterns 113. Then, the sidewall patterns 116 and 116b are formed by use of the resist patterns 115. Consequently, it is possible to form the resist patterns 113 to have a height for preventing their collapse in the memory cell region R_{M}, while overcoming the shortage of remaining film thickness in the peripheral circuit region R_{P}.

Further, by applying this pattern formation method to a manufacturing method of a nonvolatile semiconductor memory device, it is possible to form an odd number of memory cells MC between the selection gate transistors ST1 and ST2.

### Second Embodiment

The first embodiment has been exemplified by a case where a sidewall processing process is performed once to process the processing object film. The second embodiment will be exemplified by a case where a sidewall processing process is performed twice to process the processing object film.

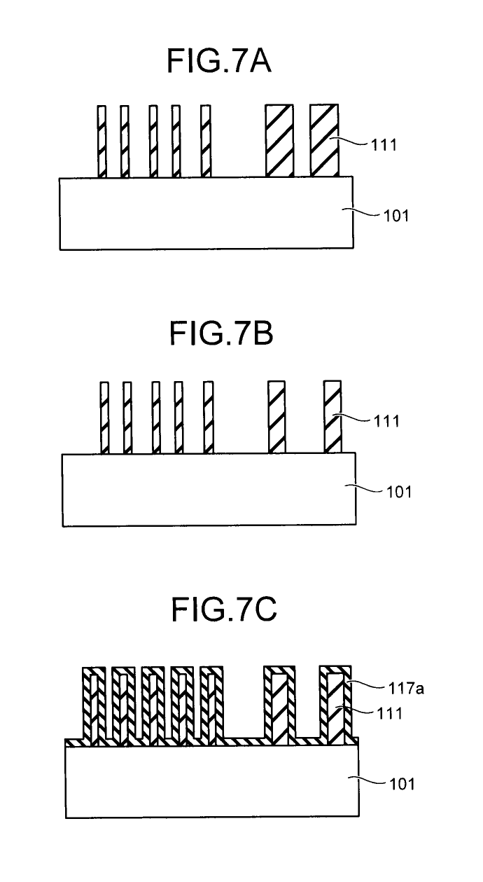

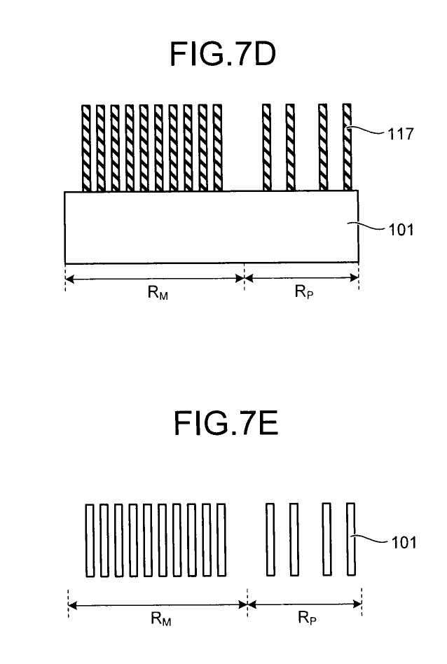

FIGS. 7A to 7E are partial sectional views schematically showing an example of a pattern formation method according to the second embodiment. Here, this method is partly the same as that of the first embodiment in terms of the steps of up to FIG. 4G, and so their description will be omitted. Further, here, manufacturing steps are shown only about part of the memory cell region R_{M} and the peripheral circuit region R_{P}.

After FIG. 4G, as shown in FIG. 7A, the intermediate film 112 and the sidewall patterns 114, 116, and 116b on the mask film 111 are removed. In the second embodiment, the mask film 111 also serves as a core material film.

Then, as shown in FIG. 7B, a slimming process for reducing the width of the mask film 111 in a cross section perpendicular to the extending direction of the mask film 111 is performed by use of wet etching or dry etching. For example, the slimming is performed to reduce the width of the mask film 111 to half. Here, the removing process of the intermediate film 112 and the sidewall patterns 114, 116, and 116b shown in FIG. 7A and the slimming process shown in FIG. 7B may be replaced with each other in the order.

Thereafter, as shown in FIG. 7C, a sidewall film 117a is formed on the processing object film 101 including the mask film 111 formed thereon and subjected to the slimming. The sidewall film 117a is formed to cover the side surfaces and upper surfaces of the mask film 111. The thickness of the sidewall film 117a may be set substantially equal to the width of the mask film 111, for example. The sidewall film 117a may be formed of an oxide film, such as a silicon oxide film, for example.

Then, as shown in FIG. 7D, the sidewall film 117a is etched back by use of wet etching or dry etching. More specifically, part of the sidewall film 117a on the mask film 111 and the processing object film 101 is removed, so that sidewall patterns 117 formed of part of the sidewall film 117a are formed around the mask film 111.

Further, the mask film 111 is removed by use of wet etching or dry etching. Consequently, the sidewall patterns 117 each having a looped shape are formed on the processing object film 101. When the slimming is performed to reduce the width of the mask film 111 to half in FIG. 7B, sidewall patterns 117 in a line-and-space form are formed in the memory cell region R_{M}. The width of the sidewall patterns 117 is almost equal to the width of the mask film 111 subjected to the slimming. Further, the width of the spaces between the sidewall patterns 117 is almost equal to the width of the sidewall patterns 117.

Thereafter, as shown in FIG. 7E, the processing object film 101 is processed, through the sidewall patterns 117 serving as a mask, by use of wet etching or dry etching. Consequently, the pattern formation method is completed.

According to the second embodiment, it is possible to form memory cells MC each having a smaller channel length as compared with the first embodiment, in addition to the effects obtained by the first embodiment.

### Third Embodiment

The first embodiment has been exemplified by a case where, when the sidewall patterns are transferred onto the intermediate film and the mask film, the etching is performed under conditions by which deposits due to the etching are not deposited on the side surfaces of the mask film. The third embodiment will be exemplified by a case where the etching is performed under conditions by which deposits due to the etching are deposited on the side surfaces of the mask film.

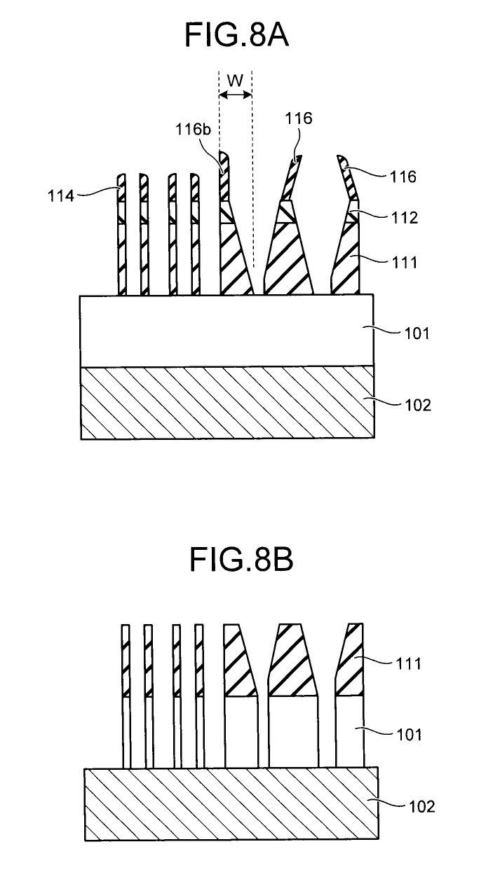

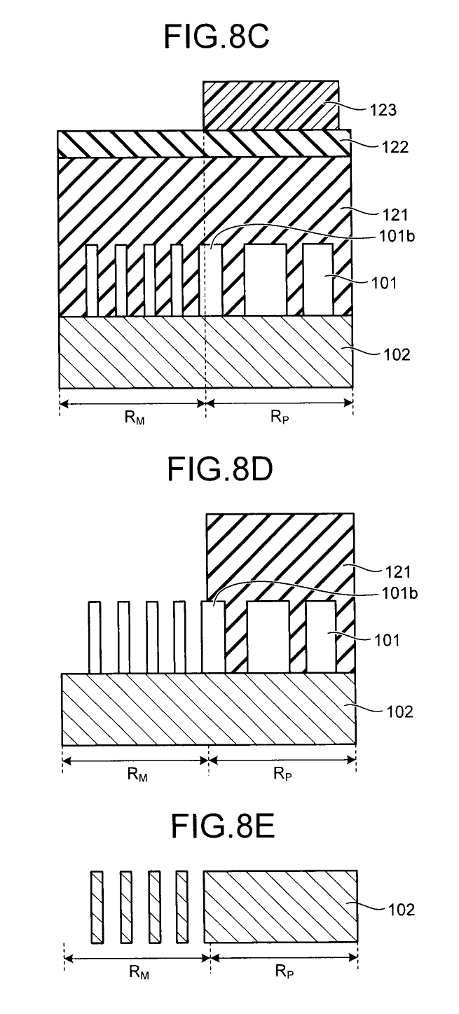

FIGS. 8A to 8E are partial sectional views schematically showing an example of a pattern formation method according to the third embodiment. Here, this method is partly the same as that of the first embodiment in terms of the steps of up to FIG. 4F, and so their description will be omitted. Further, here, manufacturing steps are shown only about part of the memory cell region R_{M} and the peripheral circuit region R_{P}.

Unlike the first embodiment, in third embodiment, a processing object film 102 is further provided below the processing object film 101. In the case illustrated in the first embodiment, the processing object film 101 becomes stacked bodies each composed of a tunnel insulating film, a floating gate electrode film, an inter-electrode insulating film, and a control gate electrode film. In the case illustrated in the third embodiment, the processing object film 102 becomes stacked bodies each composed of a tunnel insulating film, a floating gate electrode film, an inter-electrode insulating film, and a control gate electrode film.

After FIG. 4F, as shown in FIG. 8A, the intermediate film 112 is etched, through the sidewall patterns 114, 116, and 116b serving as a mask, by use of wet etching or dry etching, Consequently, the shape of the sidewall patterns 114, 116, and 116b is transferred onto the intermediate film 112. Further, the mask film 111 is etched, through the sidewall patterns 114, 116, and 116b and the patterned intermediate film 112, which serve as a mask, by use of wet etching or dry etching. Consequently, the shape of the sidewall patterns 114, 116, and 116b is transferred onto the mask film 111.

Here, if the sidewall patterns 114, 116, and 116b disappear when the pattern transfer is performed to the intermediate film 112, the pattern transfer may be performed to the mask film 111 only by the intermediate film 112. Thereafter, the intermediate film 112 and the sidewall patterns 114, 116, and 116b on the mask film 111 are removed. Here, the sidewall patterns 114, 116, and 116b and the intermediate film 112 may be set to disappear when the pattern transfer is performed to the mask film 111, by adjusting their thicknesses.

For the etching described above, an RIE method employing a fluorocarbon based gas is used to perform the etching under conditions by which deposits due to the etching are deposited on the side surfaces of the mask film 111. Consequently, in the peripheral circuit region R_{P} having larger intervals between adjacent patterns, deposits generated by a reaction are deposited on the side surfaces of the mask film 111, and the width W of the patterned mask film 111 here thereby becomes larger as compared with the first embodiment. Further, each of the openings formed at etched portions becomes a state where its width decreases downward. On the other hand, in the memory cell region R_{M} having smaller intervals between adjacent patterns, deposits generated by a reaction can hardly enter the spaces between the patterns. Consequently, the width of the patterned mask film 111 here is the same as that of first embodiment. In this respect, the width of the portion formed from the patterned mask film 111 by use of the sidewall pattern 116b is preferably larger.

Also in this case, the width of the portions formed from the intermediate film 112 and the mask film 111 by use of the sidewall pattern 116b becomes larger than the width of the portions formed from the intermediate film 112 and the mask film 111 by use of the sidewall patterns 114, and becomes smaller than the width of the portions formed from the intermediate film 112 and the mask film 111 by use of the sidewall patterns 116. Further, the sidewall pattern 116b is formed between the peripheral circuit region R_{P} and the memory cell region R_{M}.

Thereafter, as shown in FIG. 8B, the processing object film 101 is etched, through the mask film 111 serving as a mask, by use of wet etching or dry etching. Consequently, desired patterns are formed in the memory cell region R_{M} and the peripheral circuit region R_{P}.

Then, the mask film 111 is removed. Thereafter, as shown in FIG. 8C, a mask film 121 is formed on the substrate including the patterned processing object film 101, and an intermediate film 122 is further formed on the mask film 121. The mask film 121 is formed such that it fills the spaces between the patterns of the mask film 111 and reaches a position higher than the upper surface of the mask film 111. The mask film 121 may be formed of a carbon film formed by a coating method, for example. Further, the intermediate film 122 may be formed of an oxide film, such as an SOG film, for example. The mask film 121 and the intermediate film 122 correspond to a mask layer.

Further, a resist is applied onto the intermediate film 122, and a resist pattern 123 corresponding to a pattern having a size to be formed in the peripheral circuit region R_{P} is formed by use of a lithography technique. The resist pattern 123 is a pattern having a shape spreading over a plurality of segmented patterns of the processing object film 101 formed in the peripheral circuit region R_{P}. At this time, patterning is performed such that the end of the resist pattern 123 on the memory cell region R_{M} side is positioned above a pattern 101b of the processing object film 101 formed between the peripheral circuit region R_{P} and the memory cell region R_{M}. In other words, the patterning of the resist pattern 123 is performed by use of the pattern 101b as a mark. Here, since the pattern 101b has a fatter width as compared with the patterns of the processing object film 101 formed in the memory cell region R_{M}, the positioning can be easily performed.

Thereafter, as shown in FIG. 8D, the shape of the resist pattern 123 is transferred onto the intermediate film 122, and the shape of the intermediate film 122 is further transferred onto the mask film 121, by use of wet etching or dry etching. At this time, the etching is performed until part of the mask film 121 embedded between the patterns of the processing object film 101 in the memory cell region R_{M} is removed. Consequently, in the peripheral circuit region R_{P}, a mask is formed of the patterned processing object film 101 and part of the mask film 121 embedded between its patterns. Further, in the memory cell region R_{M}, a mask is formed of the patterned processing object film 101.

Then, as shown in FIG. 8E, the processing object film 102 is processed, through the processing object film 101 and the mask film 121, which serve as a mask, by use of wet etching or dry etching. Then, the processing object film 101 and the mask film 121 on the processing object film 102 are removed. Consequently, the pattern formation method according to the third embodiment is completed.

According to the third embodiment, when the intermediate film 112 and the mask film 111 are etched through the sidewall patterns 114, 116, and 116b serving as a mask, the etching is performed under conditions by which the mask film 111 is fattened. Consequently, the portion of the mask film 111 etched through the sidewall pattern 116b positioned between the peripheral circuit region R_{P} and the memory cell region R_{M} is fattened. Then, etching is performed, through the patterned mask film 111 serving as a mask, to pattern the processing object film 101. The mask film 121 is formed on the processing object film 101 thus patterned, and the resist pattern 123 is formed such that it has one end positioned above the pattern 101b between the peripheral circuit region R_{P} and the memory cell region R_{M}, and covers a plurality of patterns of the processing object film 101 in the peripheral circuit region R_{P}. Then, through the resist pattern 123 serving as a mask, the processing object film 102 below the processing object film 101 is processed. The pattern 101b positioned between the peripheral circuit region R_{P} and the memory cell region R_{M} cannot be used as a memory cell MC, but can be used as a positioning mark when the resist pattern 123 is formed to cover a plurality of patterns of the processing object film 101 in the peripheral circuit region R_{P}. As a result, it is possible to prevent a pattern of the processing object film 102, formed by use of the resist pattern 123 as a mask, from being positioned in the memory cell region RM.

In the explanation described above, a manufacturing method of a nonvolatile semiconductor memory device of the planer type having a stacked gate structure is taken as an example, but the embodiments are not limited to this example. For example, the embodiments may be applied to a semiconductor device having a configuration in which memory cells of a ReRAM (Resistive Random Access Memory), MRAM (Magnetoresistive Random Access Memory), or DRAM (Dynamic Random Access Memory) are arranged in a three-dimensional state.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a pair of selection gate transistors arranged on a semiconductor layer; and
memory cell transistors arranged on the semiconductor layer between the pair of selection gate transistors, the memory cell transistors being connected to each other in series such that every two adjacent ones of the memory cell transistors share a source/drain region,
wherein the memory cell transistors are arranged in an odd number between the pair of selection gate transistors.

2. The semiconductor device according to claim 1, wherein one of the memory cell transistors adjacent to one selection gate transistor of the pair of selection gate transistors has a gate length that is smaller than a gate length of the selection gate transistors and is larger than a gate length of the others of the memory cell transistors.

3. The semiconductor device according to claim 2, wherein
each of the memory cell transistors has a stacked gate structure in which a tunnel insulating film, a floating gate electrode film, an inter-electrode insulating film, and a control gate electrode film are stacked on the semiconductor layer, and
each of the selection gate transistor has a gate structure in which the tunnel insulating film, the floating gate electrode film, the inter-electrode insulating film, and the control gate electrode film are stacked on the semiconductor layer, and the control gate electrode film penetrates the inter-electrode insulating film and comes in contact with the floating gate electrode film in the gate structure.

4. A manufacturing method of a semiconductor device, the method comprising:
forming a first mask layer above a processing object film;
forming a first resist pattern having a first size on the first mask layer in a memory cell region by use of a lithography technique;
forming a first sidewall film having a first thickness on the first mask layer;
etching back the first sidewall film;
removing the first resist pattern;
forming a second resist pattern having a second size larger than the first size on the first mask layer in the memory cell region and a peripheral circuit region by use of a lithography technique;
forming a second sidewall film having a second thickness on the first mask layer;
etching back the second sidewall film;
removing the second resist pattern;
etching the first mask layer through the second sidewall film serving as a mask; and
etching the processing object film.

5. The manufacturing method of a semiconductor device according to claim 4, wherein the second resist pattern has a height larger than a height of the first resist pattern.

6. The manufacturing method of a semiconductor device according to claim 4, wherein the first resist pattern is a pattern in which line patterns having a width of the first size are arranged at predetermined intervals in a direction perpendicular to an extending direction of the line patterns.

7. The manufacturing method of a semiconductor device according to claim 4, wherein, in the forming of the second resist pattern, the second resist pattern is formed to cover the first sidewall film in the memory cell region.

8. The manufacturing method of a semiconductor device according to claim 4, wherein the etching the first mask layer is performed by use of dry etching, the dry etching being performed under conditions by which deposits due to the dry etching are not deposited on the first mask layer.

9. The manufacturing method of a semiconductor device according to claim 8, wherein
the processing object film includes a tunnel insulating film, a floating gate electrode film, an inter-electrode insulating film, and a control gate electrode film stacked in this order on a semiconductor layer, and
in the removing of the second resist pattern, the second sidewall film formed adjacent to the first sidewall film is used as a mask forming memory cell transistors.

10. The manufacturing method of a semiconductor device according to claim 4, further comprising:
performing slimming to the first mask layer after the etching the first mask layer;
forming a third sidewall film having a third thickness above the processing object film;
etching back the third sidewall film; and
removing the first mask layer,
wherein, in the etching of the processing object film, the processing object film is etched using the third sidewall film as mask.

11. The manufacturing method of a semiconductor device according to claim 10, wherein the third thickness is smaller than the first thickness.

12. The manufacturing method of a semiconductor device according to claim 10, wherein the third thickness is substantially equal to a width of the first mask layer subjected to the slimming.

13. The manufacturing method of a semiconductor device according to claim 4, wherein the first resist pattern is formed only in the memory cell region.

14. A manufacturing method of a semiconductor device, the method comprising:
forming a second processing object film and a first mask layer on a first processing object film;
forming a first resist pattern having a first size on the first mask layer in a memory cell region by use of a lithography technique;
forming a first sidewall film having a first thickness on the first mask layer;
etching back the first sidewall film;
removing the first resist pattern;
forming a second resist pattern having a second size larger than the first size on the first mask layer in the memory cell region and a peripheral circuit region by use of a lithography technique;
forming a second sidewall film having a second thickness on the first mask layer;
etching back the second sidewall film;
removing the second resist pattern;
etching the first mask layer through the second sidewall film serving as a mask;
etching the second processing object film through the first mask layer serving as a mask;
forming a second mask layer on the first processing object film including the second processing object film thus processed;
forming a third resist pattern having a third size on the second mask layer in the peripheral circuit region by use of a lithography technique;
etching the second mask layer through the third resist pattern serving as a mask; and
etching the first processing object film through the second mask layer and the second processing object film, which serve as a mask,
wherein the forming a third resist pattern includes positioning the third resist pattern to have its end arranged above a portion of the second sidewall film formed adjacent to the first sidewall film.

15. The manufacturing method of a semiconductor device according to claim 14, wherein the etching the first mask layer is performed by use of dry etching, the dry etching being performed under conditions by which deposits due to the dry etching are deposited on the first mask layer.

16. The manufacturing method of a semiconductor device according to claim 14, wherein the second resist pattern has a height larger than a height of the first resist pattern.

17. The manufacturing method of a semiconductor device according to claim 14, wherein the first resist pattern is a pattern in which line patterns having a width of the first size are arranged at predetermined intervals in a direction perpendicular to an extending direction of the line patterns.

18. The manufacturing method of a semiconductor device according to claim 14, wherein, in the forming of the second resist pattern, the second resist pattern is formed to cover the first sidewall film in the memory cell region.

19. The manufacturing method of a semiconductor device according to claim 14, wherein the third resist pattern is formed to spread over a plurality of patterns of the first processing object film in the peripheral circuit region.
